(19) United States
(12) Patent Application Publication
(10) Pub. No.: US 2021/0210668 A1
(43) Pub. Date: Jul. 8, 2021

(54) INTEGRATED SELF-POWERED HEATING SYSTEM

(71) Applicant: GAS TECHNOLOGY INSTITUTE, Des Plaines, IL (US)

(72) Inventors: Hamid Abbasi, Naperville, IL (US); David Cygan, Villa Park, IL (US); Sandeep Alavandi, Schaumburg, IL (US)

(73) Assignee: GAS TECHNOLOGY INSTITUTE, Des Plaines, IL (US)

(21) Appl. No.: 17/141,711

(22) Filed: Jan. 5, 2021

Related U.S. Application Data
(60) Provisional application No. 62/958,112, filed on Jan. 7, 2020.

(51) Int. Cl. H01L 35/30; F23C 3/00

(52) U.S. Cl. CPC H01L 35/30; F24D 5/08; F23C 3/002

(57) ABSTRACT

An apparatus and method for producing heat and electricity including a burner to produce radiant heat. A thermal-to-electric conversion device is integrated with the burner and proximate to the radiant heat. The conversion device provides a first side disposed toward the radiant heat and a second side disposed toward a cooling fluid flow path, such as combustion air for the burner or a media to be heated by the burner.

### CROSS REFERENCE TO RELATED APPLICATION

This application claims the benefit of U.S. provisional application, Ser. No. 62/958,112 filed on 7 Jan. 2020. The co-pending provisional application is hereby incorporated by reference herein in its entirety and is made a part hereof, including but not limited to those portions which specifically appear hereinafter.

### BACKGROUND OF THE INVENTION

### Field of the Invention

This invention relates to a self-powered heating system, and more particularly to an apparatus for producing heat and electricity with a thermal-to-electric generator integrated with the apparatus.

### Description of Related Art

Fossil fuel driven heating systems, for example, water heaters, boilers, and furnaces, are commonly dependent on electricity for start-up, operation and safety. Electricity is often provided from a grid during normal operation of such heating systems. In case of power outages, these systems are forced to shut down leading to significant heat and/or production losses. Likewise, remote or temporary locations may lack access to the grid. Modifications integrating boilers and furnace heating systems with thermal-to-electric (“TE”) conversion devices have been proposed in response, however, developing self-powered appliances for grid-independence has not resulted in successful products due to poor TE conversion leading to high capital costs.

Therefore, there is a continuing need for improved heating systems using TE devices. The claimed invention integrates a thermal-to-electric conversion device that generates electric power to self-power heating systems and/or generate excess power.

### SUMMARY OF THE INVENTION

This invention provides a burner apparatus for producing heat and electricity. In embodiments of this invention, the apparatus includes a radiant heat source, such as a burner, a cooling fluid flow path, and a thermal-to-electric conversion device, such as between the radiant heat source and the cooling fluid path. The conversion device is integrated with the burner and proximate to the radiant heat. The conversion device has a first side disposed toward the radiant heat and a second side disposed toward the cooling fluid flow path, which results in the production of electric power during burner use. The burner of this invention produces a flame or equivalent, and the first side of the conversion device is disposed facing the flame. The burner can include a flame housing at least partially surrounding a radiant heat zone including the flame, and the conversion device is connected to the flame housing with the first side disposed toward the radiant heat zone. The cooling fluid flow path desirably extends through the flame housing.

In one embodiment of this invention, the burner includes a flame housing at least partially surrounding a flame holder. The conversion device is connected to the flame housing with the first side disposed toward the flame holder. The cooling fluid flow path extends through the flame housing and can include an air flow outlet to introduce air to the flame holder.

In embodiments of this invention, the first side of the conversion device is generally parallel to a longitudinal direction of the flame. The first side of the conversion device may also face the flame holder and/or the flame at an angle at or between 0 and 90 degrees relative to the longitudinal direction of the flame. The conversion device may also include at least one fin, or equivalent structure, on the second side of the conversion device. The fin(s) increase(s) heat transfer between the conversion device and the cooling fluid flow path.

The thermal-to-electric conversion device of this invention can be a thermoelectric generator (TEG). Embodiments of this invention may include more than one TEG.

Combustion air is typically introduced into the burner apparatus to provide the flame. A first portion of the combustion air can be mixed with a fuel to then result in the flame at a flame holder. A second portion of the combustion air can enter the cooling fluid flow path and provide cooling for the second side of the TEG.

This invention also includes a method for providing heat and electricity to a machine. The method includes introducing fuel and air to a burner having a flame housing, producing radiant heat at least partially inside the flame housing, and converting thermal energy to electric energy with a thermal-to-electric conversion device integrated with the flame housing. The thermal-to-electric conversion device includes a first side disposed toward the radiant heat. The thermal-to-electric conversion device also includes a second side disposed toward a cooling fluid flow path within the flame housing.

Other objects and advantages will be apparent to those skilled in the art from the following detailed description taken in conjunction with the appended claims and drawings.

### BRIEF DESCRIPTION OF THE DRAWINGS

FIG. 1 is a schematic view of an apparatus for producing heat and electricity according to one embodiment of the invention;

FIG. 2 is a schematic view of an apparatus for producing heat and electricity according to one embodiment of the invention;

FIG. 3 is a schematic view of an apparatus for producing heat and electricity according to one embodiment of the invention;

FIG. 4 is a partial schematic view of a burner according to one embodiment of the invention;

FIG. 5 is a partial schematic view of a burner according to one embodiment of the invention;

FIG. 6 is a side view of an apparatus for producing heat and electricity in a device according to one embodiment of the invention;

FIG. 7 is a schematic view of an apparatus for producing heat and electricity according to one embodiment of the invention;

FIG. 8 is a schematic view of a thermoelectric generator (TEG) according to one embodiment of the invention;

FIG. 9 is a schematic view of a thermoelectric generator (TEG) according to one embodiment of the invention; and

FIG. 10 is a schematic view of a thermoelectric generator (TEG) according to one embodiment of the invention.

### DETAILED DESCRIPTION

One of the key challenges for thermal-to-electric (TE) conversion devices is to increase TE conversion efficiency. As described in greater detail below, the subject invention generally relates to an apparatus and method for improving TE conversion efficiency in self-powering heating systems by providing an integration solution with or at a burner.

In embodiments of this invention, heat for a first, thermal side of a TE conversion device is provided by radiant heat directly to the first side, preferably from a flame within a burner. The conversion device can be optimally located in or proximate to the burner. The integration of a combustion-driven TE device power system such as in this invention, is interconnected and interdependent on thermal characteristics and efficiencies of both the burner and the conversion device. Locating a conversion device proximate to a burner according to embodiments of this invention can simplify heating and cooling the conversion device using combustion air and/or fuel. Cooling can be effectively achieved using at least one of combustion air, fuel, or other material used in a heating device, e.g., water. The same approach can be applied when utilizing multiple heating devices to provide increased heating and cooling for maximized output of electric power generated from the conversion device. Inclusion of proximate controls can further simplify electrical connection and wiring.

Locating a conversion device proximate a burner according to this invention also reduces exposure to condensation, thereby increasing conversion device durability. For example, a 3D-printed burner with an integrated 3D-printed TE conversion device can optimize integration. A conversion device (or multiple conversion devices) can be at least partially 3D-printed along with a burner as a single unit. In one embodiment of the invention, at least part of a conversion device is printed integral with a burner. The conversion device of this invention can be cooled naturally or forced convectively to increase cooling effectiveness, thereby increasing output from the conversion device and providing long-term operation of the conversion device. The apparatus of the invention can also be subsequently expanded to other equipment such as military equipment or remote off-grid installations, and can be used in commercial and residential buildings.

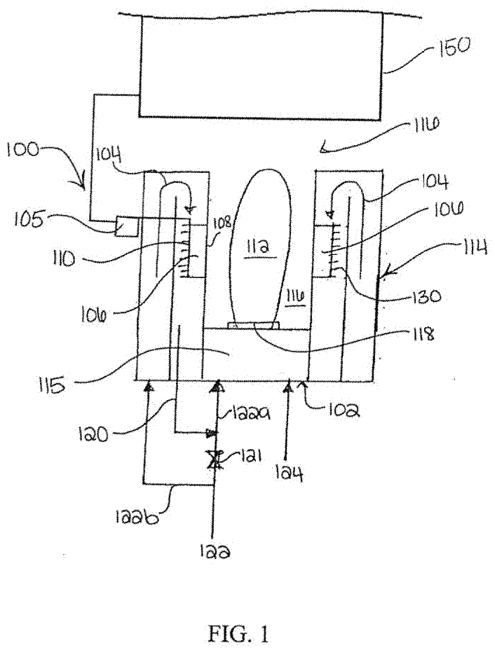

FIG. 1 schematically illustrates a TE conversion device in a heating system using a forced or induced draft burner. Burner apparatus 100 uses a burner 102 to produce radiant heat. A TE conversion device 106 is integrated with the burner 102 with a first (thermal) side 108 facing the radiant heat, more particularly, a radiant heat zone 116 including a flame 112. The conversion device 106 has a second (heat removal) side 110 that is disposed toward a cooling fluid flow path 104. The cooling flow path 104 is shown with a 180 degree turn to return back to line 122a, but can use any path configuration, such as depending on need. Generated electric energy can be collected from the conversion device 106, and stored as needed, in a power distribution device 105. The burner apparatus 100 may also include multiple conversion devices 106 integrated with the burner 102, or with more than one burner.

The burner 102 of FIG. 1 produces the flame 112 above a flame holder 118 of the burner 102. The burner apparatus 100 also includes a flame housing 114 that at least partially surrounds the radiant heat zone 116, including the flame 112. Heat produced from the burner 102 of the burner apparatus 100 is utilized in a downstream process 150 such as, a device, for example, a boiler or forced-air heater. Ideally, the device/downstream process 150 is placed in proximity to, or integrated with, the apparatus 100 so that the device 150 may receive adequate heat from the radiant heat zone 116. The conversion device 106 can be used to power the downstream process 150 using power or control connected to the burner 102. The power distribution device 105 is at least part of, or connected to, the burner 102 and includes an electronic connection to the device 150. The burner apparatus 100 can also be designed as needed to be retrofit into existing boiler or forced-air furnaces, etc.

The burner apparatus 100 includes a combustion air inlet 122 and a fuel inlet 124. The fuel inlet 124 provides fuel directly to a mixing chamber 115 of the burner 102. The mixing chamber 115 can be optional, with some or all of air and fuel could be mixed at the flame holder and/or within the flame zone. The air inlet 122 includes an optional fixed or adjustable flow restriction 121 to divert at least a portion of the combustion air flow. A first portion 122a of combustion air is directed to the mixing chamber 115 of the burner 102 to mix with fuel from the fuel inlet 124. A second portion 122b of combustion air can be directed to the cooling fluid flow path 104. In some embodiments of the invention, all combustion air can be directed to the cooling fluid flow path to cool the second side of a conversion device.

To heat the first side 108 of the conversion device 106, radiant heat and/or the flame 112 heats the first side 108 of the conversion device 106 exposed to the radiant heat zone 116. The flame 112 is generated at the flame holder 118. The flame extends above the flame holder 118 and the conversion device 106 is optimally located laterally or radially proximate to the flame 112. Proximity of the conversion device 106 within the burner 102, particularly to the flame 112 coming from the burner 102, simplifies electrical connection/conduits and also decreases impacts of burner turndown on TE conversion device output.

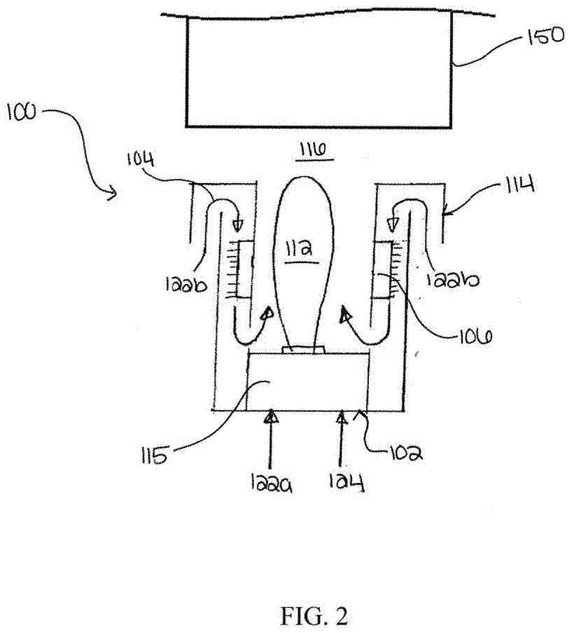

To cool the second side 110 of the conversion device 106, the cooling fluid flow path 104 utilizes incoming combustion air 122b. The incoming combustion air 122b travels through the flame housing 114 and reaches the cooling fluid flow path 104. Passing through the cooling fluid flow path 104, the air 122b passes by, and makes contact with, the second side 110 of the conversion device to cool the second side 110. After passing through the cooling fluid flow path 104, combustion air 122b passes through an air flow outlet 120 to introduce air directly to the mixing chamber 115 and up to the flame holder 118. The air flow outlet 120 can meet to combine with the first portion of combustion air 122a as shown in FIG. 1, or the air flow outlet 120 can be introduced to the flame holder 118 or a portion of the burner 102 at other alternative locations, such as shown in FIG. 2.

Other material options can also be used to cool the second side of the conversion device such as a fluid or mixture (e.g., air, fuel), a combination thereof, or a media (e.g., boiler water). A wide range of techniques can be used for directing and/or restricting combustion air flow between the first and second portions 122a, 122b, such as various valves or plates with small openings. Alternatively, different sizes of piping could be used for inlets.

As shown in FIG. 1, the flame 112 is elongated along a longitudinal axis. In other embodiments the flame as a heat source may be a wide range of shapes depending on the configuration of the burner, such as a flat flame, angular flame, conical flame, etc. The burner 102 may include any varying configuration known in the art to produce the different types of flames The flame shape can also depend on the size and shape of the flame holder. Additionally, while only one flame is shown in FIG. 1, it is to be understood that the apparatus may include multiple flames providing heat collectively to one or more conversion device. In embodiments where the burner apparatus includes more than one conversion device, multiple flames may also heat separate conversion devices. Other burner configurations may include multiple burners each with their own flame housing, multiple burners all in one flame housing, and any other suitable configuration.

In some embodiments of the invention, the flame housing 114 is fully integrated with, or is, a burner housing. The flame housing desirably at least partially surrounds or encloses at least one of the radiant heat zone, the flame, or the flame holder. In some embodiments, the flame 112 can extend past the flame housing, while in other embodiments the flame 112 can be fully within the heat zone of the flame housing.

The conversion device 106 of the invention is preferably a thermoelectric generator (TEG), although any suitable TE conversion device may be used. In embodiments of the invention where the burner apparatus includes more than one conversion device, combustion air can be directed to more than one cooling fluid flow path to cool the second side of each conversion device, while the first sides of each conversion device can be heated by one or more flames from one or more burners.

FIG. 2 shows an apparatus 100 including an aspirating burner 102. As with FIG. 1, the embodiment of FIG. 2 uses at least one flame 112 as a heat source. A first portion of combustion air, or primary air, 122a, is either mixed with fuel from fuel inlet 124, or is aspirated by the fuel resulting in the flame 112. A second portion of combustion air, or secondary air, 122b, is aspirated by the flame 112. This secondary air 122b is directed to a second side 110 of a conversion device 106 through a cooling fluid flow path 104 for that particular conversion device 106.

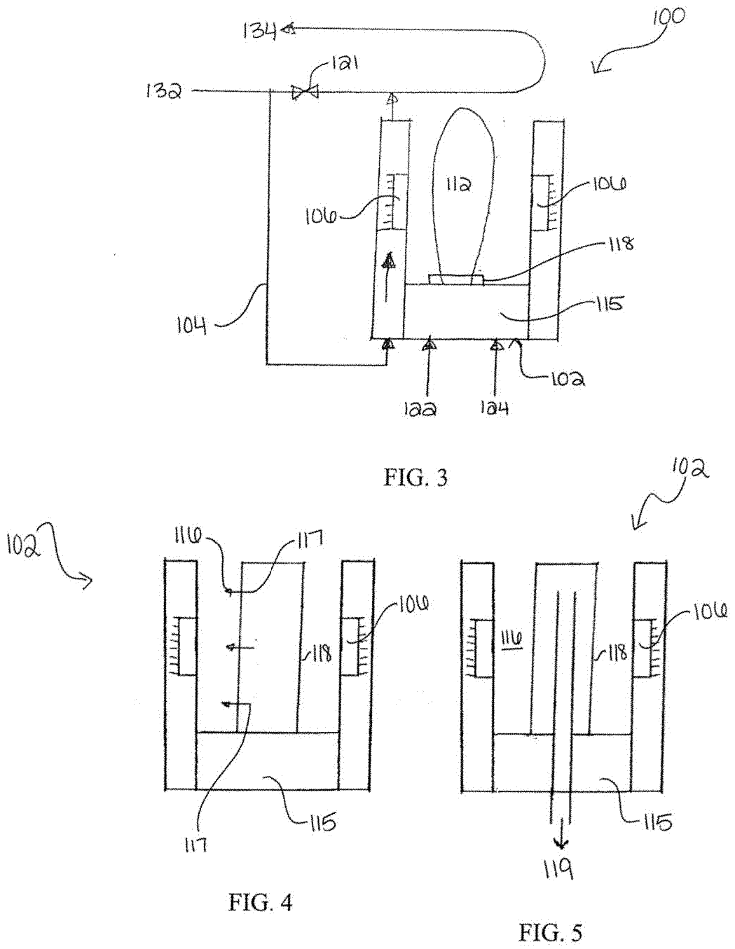

FIG. 3 shows an embodiment where a second side 110 of at least one conversion device 106 is cooled by a media, such as particles (e.g., particle laden carrier air media) or a fluid (e.g., air, water, or mineral oil). The media may be at least partially from or used in the downstream process 150 in combination with the burner 102. The media is introduced to burner apparatus 100 through a media inlet 132 where at least a portion of the media is used for the cooling fluid flow path 104. An optional fixed or adjustable flow restriction 121 to divert at least a portion of the media is included for cooling the second side 110 of one or more conversion devices 106. As will be understood by one of ordinary skill in the art, a wide range of techniques could be used for restricting the flow of the media from the inlet 132 including various valves or plates with smaller openings, or by different sized pipes. Alternatively, all the media could be directed from the inlet 132 to the second side 110 of the conversion device 106 through the cooling fluid flow path 104. After the media has passed through the cooling fluid flow path 104 and cooled the second side 110 of the conversion device 106, the media is heated from coming in contact with the conversion device 106. The heated media can proceed out of the apparatus 100 through a media outlet 134.

FIGS. 4 and 5 show alternative burner designs that can be incorporated into the burner apparatuses discussed above. FIG. 4 shows an embodiment of this invention with a burner 102 including a direct-fired heat source. The burner 102 includes a flame holder 118 that includes a hot surface heated directly by a flame to create radiant heat zone 116. The hot surface may include a metal foam matrix serving as a combustion medium, such as described in U.S. Pat. No. 9,709,265, herein incorporated by reference. Heat from the flame passes from openings 117 on the flame holder 118. The openings 117 extend through a surface of the flame holder 118 allowing heat to pass through the flame holder 118 into the radiant heat zone 116. The flame holder 118 and the openings 117 can have any suitable size, shape and configuration, depending on need.

Alternatively, FIG. 5 shows an indirect-fired heat source with a burner 102. Unlike the embodiment of FIG. 4, the flame holder 118 of FIG. 5 does not have openings. The flame holder 118, as shown in FIG. 5, holds a flame flowing inside the flame holder 118. Heat from the flame heats the flame holder 118 and cooled combustion products exit through an exhaust outlet 119. A radiant heat zone 116 is external to a hot surface of the flame holder 118. The exhaust outlet 119 passes through the flame holder 118 and the mixing chamber 115, although it is to be understood that the outlet could be in/on a variety of other suitable locations on the burner 102.

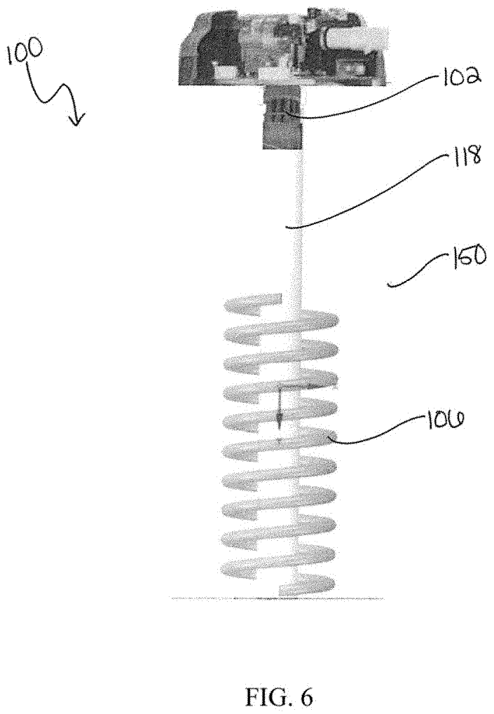

Throughout embodiments of this invention, radiant heat is provided in any number of alternative ways to heat conversion device(s), including directly from a flame and/or from a surface heated by the flame, while providing heat to a downstream heating process. Examples of radiant heat may include heat provided directly from a flame and heat provided form a surface heated by a flame. FIG. 6 shows a representation of an integrated burner 102 with a conversion device 106 in a heating system device 150. Heat can be provided to apparatus 100 by forced draft combustion where combustion air is pushed into the burner 102 by a forced draft fan upstream of the burner. Heat can also be provided by induced draft combustion where combustion air is pulled into the burner 102 by an induced draft fan downstream of the burner. Combustion air and fuel can be supplied to the apparatus 100 in a variety of ways depending on the heating system, such as, to mix in a distribution component or a combustion zone; premixing the fuel and air upstream of the burner; or providing at least a portion of fuel and/or air directly to a flame, without premixing.

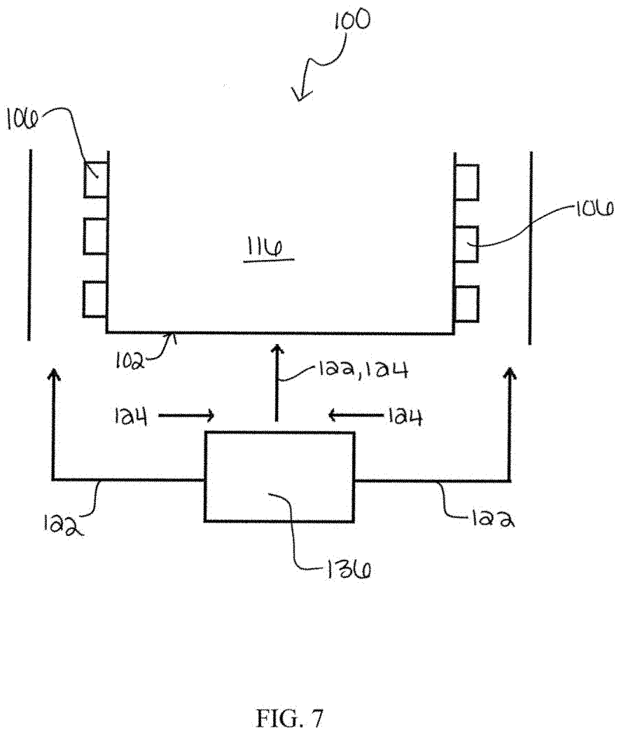

In embodiments of the invention, multiple and/or separate cooling and/or heating streams with dedicated conversion devices can be utilized to increase cooling and heating effectiveness of various devices. FIG. 7 shows a burner apparatus 100 with an integrated conversion device and burner design utilizing draft combustion with a blower 136 for conveying air 122 and fuel 124 to a burner 102. The apparatus 100 includes a plurality of conversion devices 106. The conversion devices 106 are aligned parallel to one another in a longitudinal direction of a heat source (e.g., flame) and a radiant heat zone 116. In other embodiments, conversion device(s) can be oriented at a variety of angles in relation to the heat source, preferably an angle up to 90 degrees. Multiple conversion devices can be oriented at the same angle, or each conversion device can be oriented at a different angle. Angling a conversion device in relation to a heat source can increase heat transfer on at least one of a first or second side of the conversion device. Additionally, the conversion device(s) can be desirably integrated close to the electronics (such as power distribution device 105 shown in FIG. 1), such as integrally coupled with a burner, for example, on an external wall of the burner.

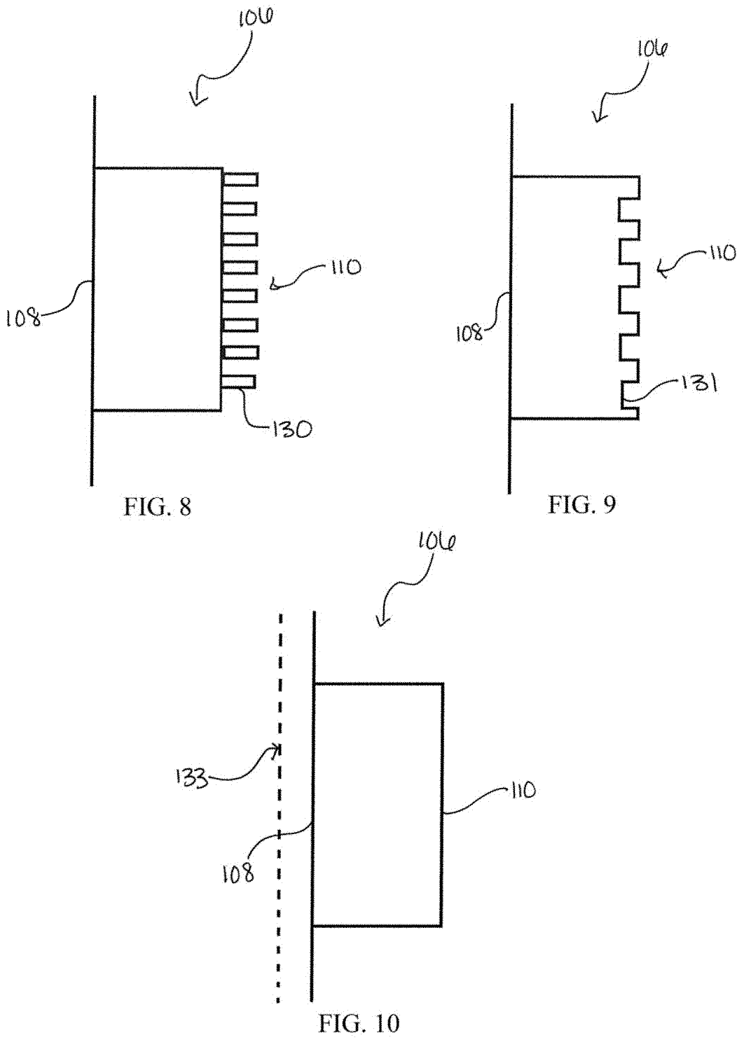

The conversion devices of the invention can additionally be equipped with surface enhancements such as pins, fins, dimples, studs, etc. to increase heat transfer. One such example, shown in FIG. 8 (and FIG. 1), includes a plurality of fins 130 on a second side 110 of a TEG 106. FIG. 9 includes dimples 131 as additional add-ons to TEG 106.

FIG. 10 shows a partition 133 included on a first side 108 of a TEG 106. The partition, which may be, for example, ceramic or metal, can be included to increase heat transfer while also protecting the conversion device 106 from overheating or damage from combustion products, thereby extending the life of the conversion device and minimizing performance degradation. The partition can also be designed to store a small amount of heat to dampen response time of the conversion device.

While in the foregoing detailed description the subject development has been described in relation to certain preferred embodiments thereof, and many details have been set forth for purposes of illustration, it will be apparent to those skilled in the art that the subject development is susceptible to additional embodiments and that certain of the details described herein can be varied considerably without departing from the basic principles of the invention.

We claim:

1. An apparatus for producing heat and electricity, the apparatus comprising:
a burner adapted to produce radiant heat;
a cooling fluid flow path; and
a thermal-to-electric conversion device integrated with the burner and proximate to the radiant heat, the conversion device having a first side disposed toward the radiant heat and a second side disposed toward the cooling fluid flow path.

2. The apparatus of claim 1, wherein the burner produces a flame and the first side of the conversion device is disposed facing the flame.

3. The apparatus of claim 1, wherein the burner comprises a flame housing at least partially surrounding a radiant heat zone, and the conversion device is connected to the flame housing with the first side disposed toward the radiant heat zone.

4. The apparatus of claim 3, wherein the cooling fluid flow path extends through the flame housing.

5. The apparatus of claim 1, wherein the burner comprises a flame housing at least partially surrounding a flame holder, and the conversion device is connected to the flame housing with the first side disposed toward the flame holder.

6. The apparatus of claim 5, wherein the cooling fluid flow path extends through the flame housing.

7. The apparatus of claim 5 wherein the cooling fluid flow path comprises an air flow outlet to introduce air to the flame holder.

8. The apparatus of claim 1, wherein the first side of the conversion device is generally parallel to a longitudinal direction of the flame.

9. The apparatus of claim 1, wherein the first side of the conversion device is disposed facing the flame at an angle at or between 0 and 90 degrees relative to a longitudinal direction of the flame.

10. The apparatus of claim 1, wherein the conversion device further comprises at least one fin on the second side of the conversion device wherein the at least one fin increases heat transfer.

11. The apparatus of claim 1, wherein the conversion device is a thermoelectric generator (TEG).

12. The apparatus of claim 11, wherein the apparatus comprises more than one TEG.

13. An apparatus for producing heat and electricity, the apparatus comprising:
a burner housing wherein the burner housing includes a burner adapted to produce radiant heat;
a cooling fluid flow path at least partially disposed through the burner housing; and
at least one thermoelectric generator (TEG) integrated with the burner and proximate to the radiant heat, the at least one TEG having a first side disposed toward the radiant heat and a second side disposed toward a portion of the cooling fluid flow path.

14. The apparatus according to claim 13 wherein the radiant heat is at least partially enclosed in the burner housing.

15. The apparatus according to claim 13 wherein a flame is at least partially enclosed in the burner housing.

16. The apparatus according to claim 13, further comprising combustion air introduced to the burner housing wherein a first portion of the combustion air is configured to mix with a fuel to provide combustion products for the radiant heat.

17. The apparatus according to claim 16 wherein a second portion of the combustion air is configured to enter the cooling fluid flow path.

18. A method for providing heat and electricity to a machine, the method comprising the steps of:
introducing fuel and air to a burner having a flame housing;
producing radiant heat at least partially inside the flame housing; and
converting thermal energy to electric energy with a thermal-to-electric conversion device integrated with the flame housing.

19. The method according to claim 18, wherein the thermal-to-electric conversion device including a first side disposed toward the radiant heat.

20. The method according to claim 18, the thermal-to-electric conversion device including a second side disposed toward a cooling fluid flow path within the flame housing.
